(19) United States
(12) Patent Application Publication
(10) Pub. No.: US 2004/0089336 A1
(43) Pub. Date: May 13, 2004

(54) Thermoelectric vaporizers, generators and heaters/coolers

(76) Inventor: Robert D. Hunt, Pass Christian, MS (US)

Correspondence Address: HARNESS, DICKEY, & PIERCE, P.L.C, 7700 BONHOMME, STE 400, ST. LOUIS, MO, 63105, US

(21) Appl. No.: 10/429,212

(22) Filed: May 1, 2003

Related U.S. Application Data
(63) Continuation-in-part of application No. 09/877,781, filed on Jun. 11, 2001, now abandoned.
(60) Provisional application No. 60/376,412, filed on May 1, 2002.

(51) Int. Cl. H01L 35/30; H01L 35/28

(52) U.S. Cl. 136/205; 136/212

(57) ABSTRACT

Apparatuses and methods for vaporizing a liquid cryogen and producing electric power, as well as devices and methods for improving the thermal contact between thermoelectric devices and heat transfer surfaces using positive and/or negative pressures. These teachings are applicable to a wide range of thermoelectric applications including thermoelectric vaporizers, thermoelectric generators and thermoelectric heaters/coolers.

### CROSS-REFERENCE TO RELATED APPLICATIONS

This application is a continuation-in-part of U.S. application Ser. No. 09/877,781 filed Jun. 11, 2001, and claims the benefit of U.S. Provisional Application No. 60/376,412 filed May 1, 2002. The entire disclosures of the aforementioned applications are incorporated herein by reference.

### BACKGROUND OF THE INVENTION

A variety of thermoelectric transducers are known in the art for converting electric current into thermal energy and vice versa. In general, when an electric current passes through such a transducer, a temperature differential is produced across opposite sides or portions thereof. This phenomenon is known as the Peltier effect. Conversely, when two sides or portions of a thermoelectric transducer have different temperatures, the transducer produces an electric current. This opposite or reverse phenomenon is known as the Seebeck effect. Thus, a thermoelectric transducer can be used to produce thermal cooling (or heating) or electric power.

In general, generating electricity thermoelectrically has been inefficient and therefore not cost effective, with thermoelectric devices transforming only about five percent of applied heat into electricity. This is due, in part, to the conductivity of heat through the p-type and n-type materials used in thermoelectric devices.

Another problem encountered with thermoelectric devices is the poor thermal contact that can exist between a thermoelectric module and the hot and cold surfaces used to conduct heat and/or cold to or from the thermoelectric module. Existing thermoelectric coolers and thermoelectric generators frequently use springs, clamps and other mechanical devices for holding thermoelectric modules in contact with heat transfer surfaces. These mechanical devices tend to fail over time, however, including when subjected to severe vibrations. Additionally, poor thermal contact can arise from corrosion between a thermoelectric module and the mechanical devices intended to provide good thermal contact with heat transfer surface(s).

In addition, electrolysis and oxidation of electrical wire connections to thermoelectric modules are among the leading causes of failures in thermoelectric modules. Further, foreign substances such as grease, soot, and dust often interfere with the operation of thermoelectric devices.

### SUMMARY OF THE INVENTION

The inventor hereof has succeeded at designing apparatuses and methods for improving the thermal contact between thermoelectric devices and heat transfer surfaces using positive and/or negative pressures. The inventor has also succeeded at designing apparatuses and methods for simultaneously vaporizing a liquid cryogen and producing electric power thermoelectrically. These teachings are applicable to a wide range of thermoelectric applications including thermoelectric vaporizers, thermoelectric generators, and thermoelectric heaters/coolers.

A method according to one aspect of the present invention includes providing a thermoelectric module and a heat transfer surface, and using at least one of positive pressure and negative pressure to force the thermoelectric module against the heat transfer surface.

An apparatus according to another aspect of the invention includes a biasing member for providing a biasing force, a thermoelectric module, and at least one rigid device positioned between the biasing member and the thermoelectric module for coupling the biasing force of the biasing member to one side of the thermoelectric module.

A method according to another aspect of the present invention includes providing an apparatus having an inlet for receiving a cryogen in liquid form, an outlet for supplying vapor produced from the cryogen, at least one thermoelectric device for producing electric power, and electric terminals for supplying the electric power. The method further includes inputting a cryogen in liquid form into the inlet, and thermally coupling one side of the thermoelectric device to the cryogen and another side of the thermoelectric device to a heat source to produce a temperature differential across the thermoelectric device. The thermoelectric device produces electric power in-response to the temperature differential. The method also includes transferring heat to cryogen within the apparatus, at least a portion of the cryogen within the apparatus vaporizing in response to the transferred heat, and outputting the produced electric power via the electric terminals and the produced vapor via the outlet.

Additional aspects and features of the invention will be in part apparent and in part pointed out below.

### BRIEF DESCRIPTION OF THE DRAWINGS

FIG. 1 is a sectional view of a thermoelectric device employing negative pressure for providing good thermal contact with a heat transfer surface;

FIGS. 2A and 2B are sectional views of thermoelectric devices employing biasing members for providing good thermal contact with a heat transfer surface;

FIG. 3 is a block diagram of a thermoelectric vaporizer/generator according to another embodiment of the invention;

FIGS. 4A-4C illustrate a tubular thermoelectric vaporizer having a wall formed of alternating layers of p-type and n-type materials;

FIG. 5 illustrates a vacuum insulated thermoelectric heat exchanger according to another embodiment of the invention;

FIGS. 6 and 7 are sectional views of vacuum insulated thermoelectric heat exchangers according to additional embodiments of the invention;

FIGS. 8A and 8B depict a thermoelectric vaporizer having a solar heat collector according to another embodiment of the invention;

FIGS. 9A-9D illustrate a thermoelectric vaporizer according to yet another embodiment of the invention; and

FIG. 10 is a sectional view of a thermoelectric heat exchanger according to still another embodiment of the invention.

### DETAILED DESCRIPTION OF EXEMPLARY EMBODIMENTS

A method for improving the thermal contact between a thermoelectric device and a heat transfer surface according to one aspect of the present invention includes providing a thermoelectric module and a heat transfer surface, and using positive pressure and/or negative pressure to force the thermoelectric module against the heat transfer surface. In this manner, good thermal contact between the thermoelectric module and the heat transfer surface can be attained.

An exemplary device for practicing the above-described method using negative pressure is illustrated in FIG. 1 and referred to generally by reference character 100. As shown in FIG. 1, the device 100 includes a thermoelectric module 102 positioned between a heat transfer surface 104 and a pliable material 106. Negative pressure is established in a region 108 between the pliable material 106 and the heat transfer surface 104 using, e.g., a vacuum pump (not shown). The negative pressure draws the pliable material 106 against the thermoelectric module 102 which, in turn, forces the thermoelectric module 102 against the heat transfer surface 104. In this manner, good thermal contact is established between the thermoelectric module 102 and the heat transfer surface 104, as well as between the thermoelectric module 102 and the pliable material 106.

Additionally, as the pressure drops within the region 108, the higher pressure surrounding environment (when applicable) forces the pliable material 106 against the thermoelectric module 102 and thus the thermoelectric module 102 against the heat transfer surface 104, thereby further contributing to the good thermal contact between the pliable material 106 and the thermoelectric module 102 and between the thermoelectric module 102 and the heat transfer surface 104.

In certain applications of the invention, the pliable material 106 is a thermally conductive material (e.g., a pliable metal foil), and the heat transfer surface 104 is a rigid surface.

The vacuum region 108 shown in FIG. 1 can also be used to seal the thermoelectric module 102 in an oxygen-free, dust-free and moisture-free environment, thereby protecting the thermoelectric module from such elements. Further, the vacuum region 108 can be used to reduce or eliminate lateral heat loss from the thermoelectric module 102 by requiring all heat transfer to occur across the module's two thermal contact surfaces 110, 112.

Although the thermoelectric module 102 is depicted in FIG. 1 as directly contacting the heat transfer surface 104 and the pliable material 106, it should be understood that the module 102 may be thermally coupled to the heat transfer surface 104 and/or the pliable material 106 through one or more intervening thermally conductive devices or materials.

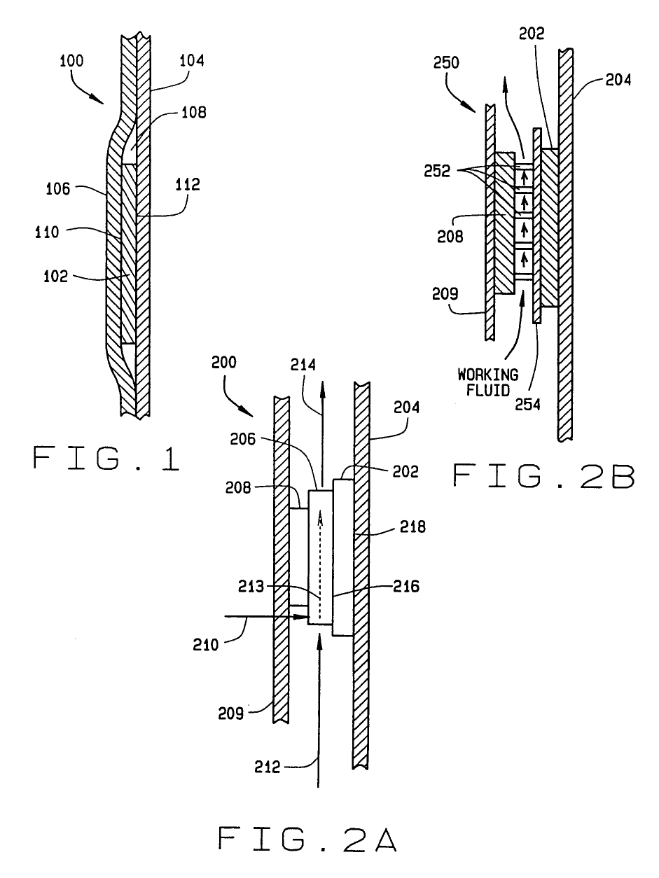

FIG. 2A illustrates a device 200 that employs positive pressure to improve the thermal contact between a thermoelectric module 202 and a heat transfer surface 204. As shown therein, a rigid device 206 is positioned between the thermoelectric module 202 and a biasing member 208. The biasing member 208 is preferably supported (directly or indirectly) on one side thereof by a rigid support surface 209. The biasing member 208 provides a biasing force 210 which is coupled to the thermoelectric module 202 through the rigid device 206 therebetween. As a result of this force 210, good thermal contact is established between the thermoelectric module 202 and the heat transfer surface 204, as well as between the rigid device 206 and the thermoelectric module 202.

In some embodiments, the rigid device 206 includes one or more fluid passages for conveying a working fluid (e.g., a liquid cryogen or a low-boiling-point liquid), as illustrated by arrows 212-214 in FIG. 2A, and the device 200 is configured for thermally coupling the working fluid to the thermoelectric module 202. For example, a fluid passage through the rigid device 206 can be located adjacent the thermoelectric module 202 such that the working fluid directly contacts a portion of the thermoelectric module 202. Alternatively (or additionally), the rigid device 206 may be thermally conductive such that the working fluid is thermally coupled to the thermoelectric module 202 through the rigid device 206. By thermally coupling the working fluid to the thermoelectric module 202, the thermoelectric module can be used to heat (or cool) the working fluid, and/or the working fluid can be used to apply heat (or cooling) to the thermoelectric module 202.

In one embodiment, the rigid device 206 is a heat sink having fins across which the working fluid flows. The heat sink thermally couples the working fluid to the thermoelectric module 202 while, at the same time, couples the biasing force 210 of the biasing member 208 to the module's two thermal contact surfaces 216, 218. It should be understood, however, that a variety of other devices can be employed as the rigid device 206.

The biasing member shown in FIG. 2A may be, for example, a spring, a pressurized air bladder, a resilient rubber material, or any other device capable of providing the biasing force 210.

As an alternative to the embodiment shown in FIG. 2A, the biasing member 208 may contact the thermoelectric module 202 directly such that the rigid device 206 can be eliminated. In such a case, the biasing member 208 may be provided, if desired, with one or more slots or channels through which a working fluid can flow with the working fluid thermally coupled to the thermoelectric module directly via direct contact with the thermoelectric module 202, indirectly via the biasing member, and/or otherwise.

The device 200 may also be configured with the thermoelectric module 202 sandwiched between multiple biasing members, as further described below.

FIG. 2B illustrates an embodiment of the device 200 shown in FIG. 2A in which the rigid device 206 takes the form of several rigid transfer rods 252 for coupling the biasing force 210 of the biasing member 208 to the thermoelectric module 202. The device 250 shown in FIG. 2B also employs a pliable heat transfer plate 254 positioned between the rigid transfer rods 252 and the thermoelectric module 202. In this manner, the biasing force 210 of the biasing member 208 can be more evenly applied across the thermoelectric module, ensuring good thermal contact at numerous points across the module's thermal contact surfaces.

FIG. 3 illustrates a device 300 for vaporizing a liquid cryogen (or a low-boiling-point liquid) and producing electric power according to another aspect of the present invention. As shown therein, the device 300 includes an inlet 302 for receiving a cryogen in liquid form, an outlet 304 for supplying vapor produced from the liquid cryogen, a thermoelectric module 306 for producing electric power, and electric terminals 308 for supplying the produced electric power.

As used herein, “liquid cryogen” refers to substances in liquid form having temperatures at or below −150° C., including, e.g., liquid hydrogen, liquid nitrogen, and liquid oxygen.

To use the device of FIG. 3, a liquid cryogen is fed into the device 300 via the inlet 302. The input cryogen 310 is thermally coupled to one side of the thermoelectric module 306 and a heat source 312 is thermally coupled to another side of the thermoelectric module 306, as indicated generally by arrows 314, 316 in FIG. 3. As a result, a temperature differential is produced across the thermoelectric module 306 from which the thermoelectric module produces electric power. Preferably at the same time, heat is transferred to the cryogen 310 within the device 300 which causes at least some of the cryogen 310 to vaporize. The produced vapor is output from the device 300 via the outlet 304, and the electric power produced by the thermoelectric module 306 is output via the terminals 308. In this manner, electric power and cryogen vapor can be produced simultaneously (if desired) from a liquid cryogen (e.g., liquid oxygen).

In some embodiments, the heat source 312 is ambient heat from the environment external to the device 300. It should be understood, however, that a variety of other heat sources may be advantageously employed. Further, while the heat source 312 is positioned external to the device 300, the device 300 may be provided with the heat source 312 therein.

Preferably, the heat transferred to the cryogen 310 is heat conducted through the thermoelectric module 306, as indicated generally by arrow 318 in FIG. 3. In this manner, the heat loss inherent in thermoelectric power generation due to thermal conduction is advantageously used to vaporize the cryogen 310. Thus, the heat 316 provided to the thermoelectric module is either converted to electricity thermoelectrically or is conducted through the module and absorbed by the cryogen 310 to vaporize liquid cryogen and/or increase the internal energy of cryogenic vapor within the device 300. Alternatively, the device 300 can be provided with a separate heat source (i.e., in addition to the heat source 312) for transferring heat to the cryogen 310.

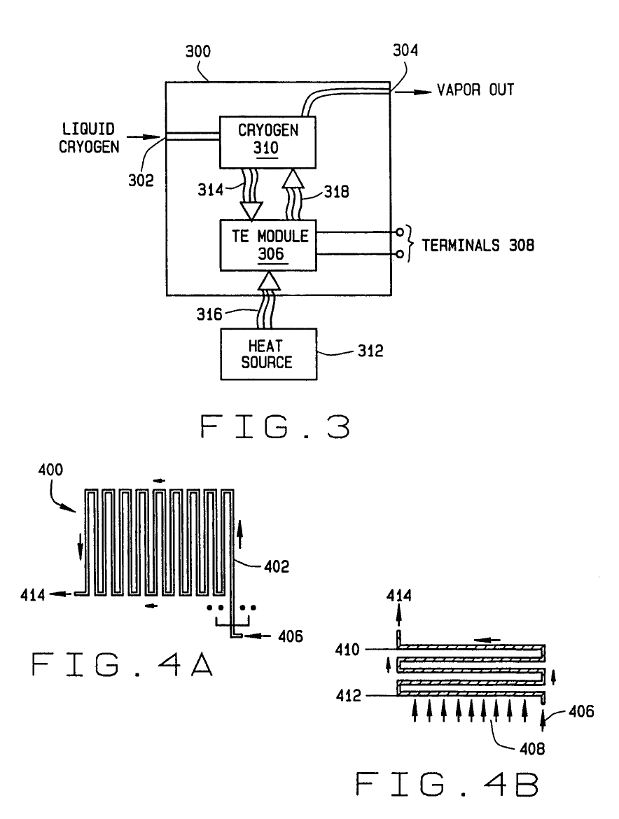

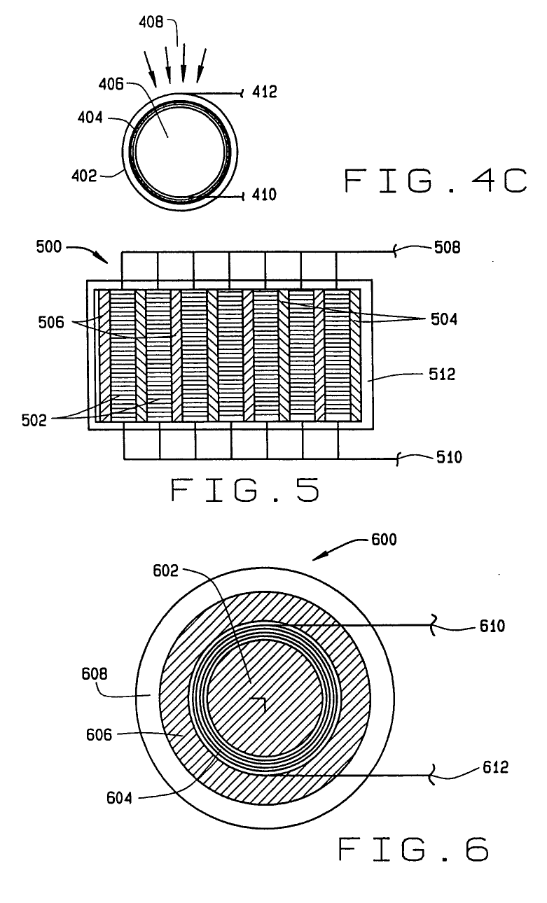

FIGS. 4A-4C illustrate a thermoelectric vaporizer 400 constructed of alternating layers of thermally and electrically conductive p-type and n-type materials according to another embodiment of the present invention. Similar to the device 300 of FIG. 3, the thermoelectric vaporizer 400 shown in FIG. 4 is capable of generating electrical power while performing as a cryogenic heat exchanger.

In this embodiment, the thermoelectric vaporizer is constructed from a tube 402 having a wall constructed from alternating layers 404 of p-type and n-type materials. A liquid cryogen 406 (or a low-boiling-point liquid) flows through the center of the tube with atmospheric heat 408 surrounding the outside of the tube. As heat penetrates the alternating layers 404 of p-type and n-type materials, electricity is generated thermoelectrically to produce a positive electrical charge 410 and a negative electrical charge 412. A portion of the heat that penetrates the alternating layers 404 is not converted into electricity, and is instead absorbed by the liquid cryogen 406 within the tube 402. This causes the liquid cryogen to vaporize and form cryogenic vapor 414 which exits another end of the tube.

A vacuum insulated thermoelectric vaporizer 500 that performs as a solid-state electric generator and as a cryogenic heat exchanger to vaporize a cryogen (or a low-boiling-point liquid) according to another embodiment of the present invention 500 is illustrated in FIG. 5. As shown therein, the vaporizer 500 is constructed of p-type and n-type materials in alternating layers with the direction of heat flow parallel to the p/n junctions. Each set 502 of alternating layers 502 is thermally coupled to a flowing liquid cryogen 504 on one side and a flowing heat source 506 on another side. In response to the temperature differentials across the sets 502 of alternating layers, the thermoelectric vaporizer 500 produces an alternating current output as a positive charge 508 and a negative charge 510.

According to another aspect of the present invention, the thermoelectric vaporizer 500 shown in FIG. 5 is surrounded by a vacuum insulation chamber 512 that isolates the sets 502 of alternating layers (as well as the heat source 502 and cryogen 504) from the external environment.

FIG. 6 illustrates another embodiment of a vacuum insulated thermoelectric vaporizer 600 according to the present invention. As shown therein, the thermoelectric vaporizer 600 is tubular in shape. A heat source 602 flows through the center of the thermoelectric vaporizer 600 and is surrounded by alternating layers 604 of p-type and n-type materials. A liquid cryogen 606 (or a low-boiling-point liquid) flows across a side of the alternating layers 604 opposite the heat source 602 such that the layers 604 of materials are between the heat source 602 and the liquid cryogen 606. The liquid cryogen flow chamber 606 is itself surrounded by a vacuum-insulation chamber 608 that isolates the alternating layers 604 (as well as the heat source 602 and cryogen 606) from the external environment. The alternating layers 604 of p-type and n-type materials generate a positive electrical current 610 and a negative electrical current 612 by converting a portion of the thermal energy from the heat source 602 into electricity. At least some of the heat from the heat source 602 that is not converted into electricity is absorbed by the cryogen 606, thereby causing the cryogen to vaporize.

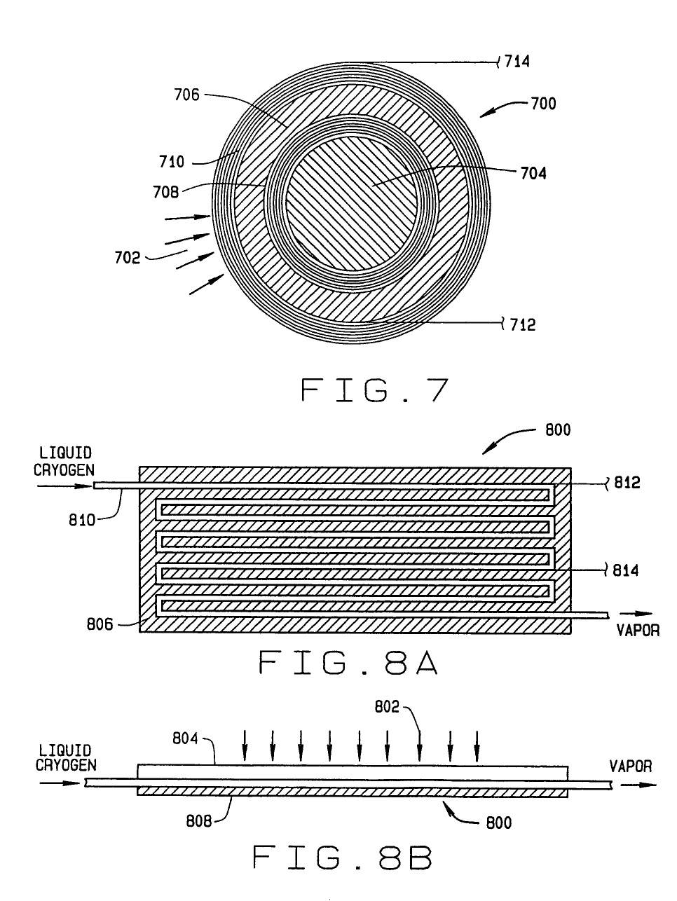

FIG. 7 depicts another embodiment of a thermoelectric vaporizer 700. In this embodiment, both an external heat source 702 and an inner heat source 704 are employed. A liquid cryogen 706 (or a low-boiling-point liquid) and the heat sources 702, 704 are separated by layers of p-type and n-type materials for producing electricity. The outer heat source 702 may be atmospheric heat and the inner heat source 704 may be, for example, the heat of compression, solar heat, geothermal water, hot exhaust gases of combustion, chemical heat, etc. Heat from the inner heat source 704 flows through the center of the thermoelectric vaporizer 700 and is surrounded by layers 708 of p-type and n-type materials. These layers 708 of material are surrounded by a liquid cryogen flow chamber 706 which itself is surrounded by another set of layers 710 of p-type and n-type materials, which are surrounded by the external heat source 702. The alternating layers 708, 710 of p-type and n-type materials generate a positive electrical current 712 and a negative electrical current 714 by converting a portion of the thermal energy from the external heat source 702 and the inner heat source 704 into electricity. At least some of the heat from the external heat source 702 and the inner heat source 704 that is not converted to electricity is absorbed by the liquid cryogen 706, causing the cryogen to vaporize.

FIGS. 8A and 8B depict a thermoelectric vaporizer 800 having a solar heat collector for vaporizing liquid air (or any other cryogen or a low-boiling-point liquid) while producing electricity. Solar radiation 802 is preferably concentrated by a fresnel lens 804 positioned on a top side of the thermoelectric vaporizer 800. The upper surface 806 of the vaporizer is preferably painted black to absorb heat. The bottom side of the thermoelectric vaporizer is preferably provided with insulation 808 to prevent heat from penetrating a bottom surface of the vaporizer. One or more tubes 810 are provided with walls constructed from alternating layers of p-type and n-type materials that generate a positive electrical current 812 and a negative electrical current 814 when a liquid cryogen flows therethrough by converting a portion of the thermal energy from the solar radiation 802 (which is a heat source) into electricity. At least some of the heat that is not converted into electricity by the alternating layers is conducted through the alternating layers and absorbed by the cryogen to produce cryogen vapor.

The produced cryogen vapor may be used to perform mechanical work. In one preferred application, the thermoelectric vaporizer 800 of FIG. 8 is located on the roof of a cryogenic vapor powered vehicle for supplying the produced vapor thereto.

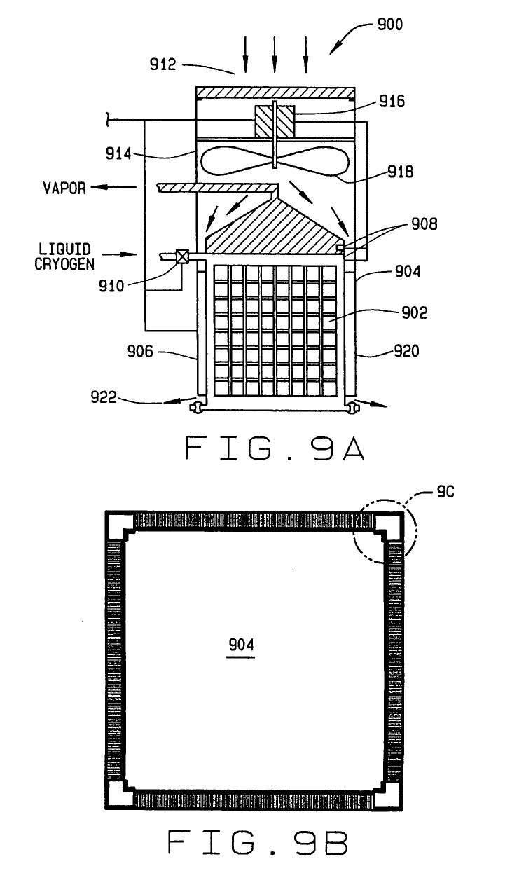

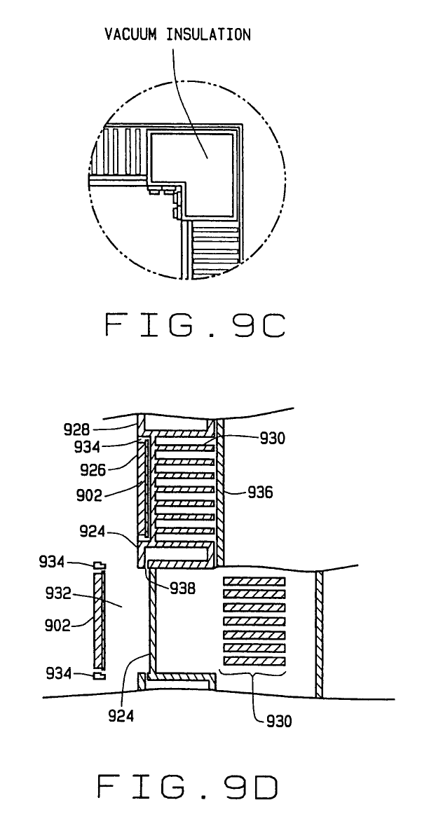

FIGS. 9A-9D depict a thermoelectric vaporizer 900 according to another embodiment of the invention. As shown therein, the thermoelectric vaporizer 900 is constructed of thermoelectric modules 902 that generate DC electric power thermoelectrically. The vaporizer 900 also includes a vessel 904 for containing liquid cryogen 906 (or a low-boiling-point liquid), as well as on/off level sensors 908 and an inlet valve 910 for controlling the level of liquid cryogen 906 within the vessel 904.

Ambient temperature air 912 is preferably drawn into a blower housing 914 of the thermoelectric vaporizer by a fan motor 916 having fan blades 918. Alternativley, other air moving means may be employed, such as an air compressor. The forced air flows though the blower housing 914 and across heat fins 920 that transfer heat from the air 912 to the thermoelectric modules 902 within the vessel 904. A portion of the heat is converted to DC current thermoelectrically by the thermoelectric modules 902. At least some of the remaining heat conducts through the thermoelectric modules 902 and is absorbed by the cryogen 906 to produce cryogen vapor. The forced air, having heat removed, is cooled and is allowed to exit the thermoelectric vaporizer as cold air 922. The cryogen vapor is output from the thermoelectric vaporizer 906 for any desired use (e.g., gaseous oxygen needed by hospitals for their patients).

As shown in FIGS. 9B-9D, the thermoelectric modules 902 are positioned inside the vessel 904 against a rigid inner wall 924 and are covered by a metal foil 926 that is sealed at edges of the vessel's wall by overlap strips 928 screwed to the inner wall 924. Heat transfer fins 930 are located on the outside of the rigid inner wall 924 in order to conduct heat to the thermoelectric modules 902. The area 932 between the rigid inner wall 924 and the metal foil 926 forms a vacuum chamber to protect the thermoelectric modules from corrosion, dirt, moisture, and other harmful effects.

FIG. 9D in particular details the mounting and vacuum seal formed for the thermoelectric modules 902. The vessel's housing is preferably a rigid material that readily conducts heat. The thermoelectric modules are mounted against the housing on the inside of the vessel with insulation material 934 filling in spaces between the modules and the housing. Heat transfer fins are attached to the outside of the housing with an outer wall 936 trapping flowing air (containing heat) between the inner wall 924 and the outer wall 936. The thermoelectric modules mounted on the inner wall 924 are covered by the pliable metal foil 926 that is allowed to draw tightly against the thermoelectric modules 902 when a vacuum is formed between the inner wall 924 and the metal foil 926. This forms a vacuum pack which seals the thermoelectric modules 902 and provides good thermal contact between the thermoelectric modules 902, the metal foil 926, and the inner wall 924. The thermal contact is enhanced by outward pressure exerted by the liquid cryogen 906 within the vessel, which applies pressure against the pliable metal foil 926 and thus the thermoelectric modules 902, causing the modules 902 to press more firmly against the rigid inner wall 924 of the vessel housing 904.

The vacuum insulation is preferably formed by a vacuum pump (not shown) that draws a vacuum between the metal foil 926 and enclosed sections of the housing 904 to prevent heat transfer in areas of the housing at which heat transfer is undesirable. Apertures 938 extend through portions of the enclosed sections below the metal foil 926 to allow such areas to be vacuumed by the vacuum pump.

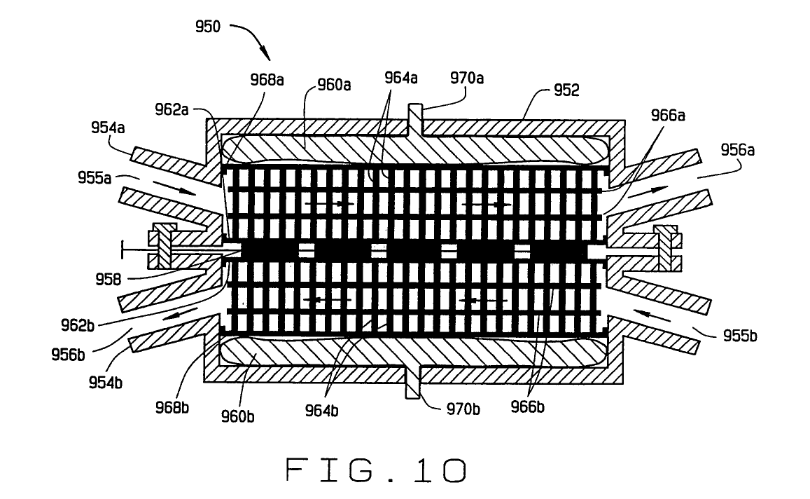

FIG. 10 illustrates a thermoelectric heat exchanger 950 according to another embodiment of the present invention. As shown therein, the heat exchanger includes a rigid housing 952 preferably formed of two substantially identical housing members 954a, 954b detachably connected to one another (e.g., via flanges and threaded fasteners). Removably positioned within the housing are several thermoelectric modules 958 sandwiched between two movable assemblies. Each assembly includes an inflatable air bladder 960a, 960b, an inner pliable plate 962a, 962b, heat/pressure transfer rods 964a, 964b, perforated alignment plates 966a, 966b, and an outer pliable plate 968a, 968b. As shown in FIG. 10, the transfer rods 964 extend through apertures in the alignment plates 966 to maintain the alignment of the transfer rods 964. Preferably, the transfer rods 964 can freely slide within such apertures.

By inflating the air bladders 960, pressure is applied to the outer pliable plates 968. This pressure is coupled from the outer pliable plates 968 to the thermoelectric modules 958 via the transfer rods 964 and the inner pliable plates 962. In this manner, good thermal contact is established between the thermoelectric modules 958 and the inner pliable plates 962, which are preferably thermally conductive. By applying equal gas pressure to the air bladders 960, equal pressure can be applied against opposite sides of the thermoelectric modules 958. Alternatively, differential pressures can be employed. Gas inlet valves 970a, 970b are provided for supplying pressurized gas to the air bladders 960, as shown in FIG. 10.

Each housing member 954a, 954b is preferably provided with inlet ports 955a, 955b and outlet ports 956a, 956b for receiving and discharging working fluids. Thus, a hot working fluid (gaseous or liquid) may flow through the upper half of the heat exchanger between the inner and outer pliable plates 962a, 968a. Similarly, a cold working fluid (gaseous or liquid) may flow through the lower half of the heat exchanger between the inner and outer pliable plates 962b, 968b.

To create a temperature differential across the thermoelectric modules 958, and thereby produce electric power, heat from the hot working fluid is transferred to the inner pliable plate 962a both directly through contact with the inner pliable plate 962a, and indirectly through the thermally conductive transfer rods 964a across which the hot working fluid flows. Similarly, cold from the cold working fluid, which acts as a heat sink, is transferred to the inner pliable plate 962b both directly through contact with the inner pliable plate 962b, as well as indirectly through the thermally conductive transfer rods 964b.

When the thermoelectric heat exchanger 950 of FIG. 10 is used as a vaporizer, a liquid cryogen or liquid state low-boiling-point-liquid flows through the lower half of the heat exchanger. Heat from the hot working fluid that conducts through the thermoelectric modules 958 is absorbed by the liquid cryogen or the liquid state low-boiling-point-liquid, thereby causing at least some of such liquid to vaporize into the gaseous state. The produced vapor is output from the heat exchanger via the outlet 956a. Alternativley, electric power can be supplied to the thermoelectric modules for producing heat which can be transferred to the liquid cryogen or low-boiling-point-liquid for the purpose of producing vapor. Electric power can also be supplied to the thermoelectric modules 958 for heating and/or cooling working fluids without causing vaporization.

Those skilled in the art will appreciate that many changes can be made in the above embodiments without departing from the spirit and scope of the invention. Therefore, it is intended that all matter contained in the above description or shown in the accompanying drawings shall be interpreted as illustrative and not in a limiting sense.

What is claimed is:

1. A method comprising:
providing an apparatus having an inlet for receiving a cryogen in liquid form, an outlet for supplying vapor produced from said cryogen, at least one thermoelectric device for producing electric power, and electric terminals for supplying the electric power;
inputting a cryogen in liquid form into said inlet;
thermally coupling one side of the thermoelectric device to the cryogen and another side of the thermoelectric device to a heat source to produce a temperature differential across the thermoelectric device, the thermoelectric device producing electric power in response to the temperature differential;
transferring heat to cryogen within the apparatus, at least a portion of the cryogen within the apparatus vaporizing in response to the transferred heat; and
outputting the produced electric power via the electric terminals and the produced vapor via said outlet.

2. The method of claim 1 wherein the heat source is ambient heat.

3. The method of claim 1 wherein the thermoelectric device comprises alternating layers of p-type and n-type materials.

4. The method of claim 1 wherein the thermoelectric device is embodied in a wall of the apparatus.

5. The method of claim 4 wherein said wall defines a fluid passage through which the cryogen in liquid form flows.

6. The method of claim 5 wherein said wall is a tubular wall.

7. The method of claim 1 wherein the apparatus includes a vacuum chamber for insulating the thermoelectric device from an external environment.

8. The method of claim 1 wherein transferring heat includes transferring heat from said heat source to the cryogen within the apparatus.

9. The method of claim 1 wherein the heat source is solar heat.

10. The method of claim 1 wherein the apparatus includes a level sensor for controlling a level of cryogen therein.

11. A method comprising:
providing a thermoelectric module and a heat transfer surface; and
using at least one of positive gas pressure and negative pressure to force the thermoelectric module against the heat transfer surface.

12. The method of claim 11 wherein using includes using positive gas pressure.

13. The method of claim 12 wherein using positive gas pressure includes filling a pliable bladder with a pressurized gas.

14. The method of claim 13 wherein using includes coupling the pliable bladder to the thermoelectric module through a rigid device.

15. The method of claim 14 wherein coupling includes coupling the pliable bladder to the thermoelectric module through said rigid device and a pliable material in contact with the thermoelectric module.

16. The method of claim 11 wherein using includes using negative pressure.

17. The method of claim 16 wherein using negative pressure includes drawing a vacuum between a pliable material and the heat transfer surface with the thermoelectric module positioned therebetween, the pliable material forcing the thermoelectric module against the heat transfer surface.

18. The method of claim 17 further comprising applying positive pressure to a side of the pliable material opposite the thermoelectric module to further force the thermoelectric module against the heat transfer surface.

19. The method of claim 18 wherein applying positive pressure includes applying positive pressure using a liquid cryogen.

20. The method of claim 17 wherein the pliable material is a thermally conductive foil.

21. The method of claim 11 further comprising inducing a temperature differential across the thermoelectric module, the thermoelectric module producing electric power in response to the temperature differential.

22. The method of claim 11 further comprising supplying electric power to the thermoelectric module, the thermoelectric module producing a temperature differential in response to the electric power.

23. An apparatus comprising:
a biasing member for providing a biasing force;
a thermoelectric module; and
at least one rigid device positioned between the biasing member and the thermoelectric module for coupling the biasing force of the biasing member to one side of the thermoelectric module.

24. The apparatus of claim 23 further comprising an inlet, an outlet, and a fluid passage for a working fluid extending between the inlet and the outlet.

25. The apparatus of claim 24 wherein the rigid device extends through said fluid passage.

26. The apparatus of claim 25 wherein the rigid device is thermally conductive for thermally coupling the working fluid to said one side of the thermoelectric module.

27. The apparatus of claim 23 wherein said at least one rigid device comprises a plurality of rods.

28. The apparatus of claim 27 further comprising at least one spacer plate having a plurality of apertures, the plurality of rods extending through the apertures of the spacer plate.

29. The apparatus of claim 23 further comprising a housing, the housing engaging at least one end of the biasing member.

30. The apparatus of claim 29 wherein the housing comprises two substantially identical housing members detachably connected to one another.

31. The apparatus of claim 23 further comprising a pliable material positioned between the rigid device and the thermoelectric module, the rigid device coupling the biasing force of the biasing member to said one side of the thermoelectric module through the pliable material.

32. The apparatus of claim 23 wherein the biasing member is selected from the group consisting of a spring, an inflatable air bladder, and a resilient rubber material.

33. An apparatus comprising:
first and second support surfaces;
first and second biasing members engaging the first and second support surfaces, respectively;
a first plurality of rigid transfer rods coupled to the first biasing member;
a second plurality of rigid transfer rods coupled to the second biasing member; and
at least one thermoelectric module positioned between and coupled to the first plurality of rigid transfer rods and the second plurality of rigid transfer rods.

34. The apparatus of claim 33 further comprising first and second pliable heat transfer plates, the first and second pliable heat transfer plates coupling the first plurality of rigid transfer rods and the second plurality of rigid transfer rods, respectively, to the at least one thermoelectric module.

35. The apparatus of claim 34 wherein the first and second support surfaces are first and second housing members, respectively.

36. The apparatus of claim 35 wherein the first and second housing members are substantially identical.

37. the apparatus of claim 35 wherein the first and second biasing members are first and second inflatable air bladders, respectively.
